(19) United States
(12) Patent Application Publication
(10) Pub. No.: US 2014/0240565 A1
(43) Pub. Date: Aug. 28, 2014

(54) SOLID-STATE IMAGING DEVICE AND ELECTRONIC APPARATUS

(71) Applicant: Sony Corporation, Tokyo (JP)

(72) Inventor: Hirotaka Murakami, Kanagawa (JP)

(73) Assignee: Sony Corporation, Tokyo (JP)

(21) Appl. No.: 14/184,485

(22) Filed: Feb. 19, 2014

(30) Foreign Application Priority Data
Feb. 26, 2013 (JP) 2013-036303

(51) Int. Cl. H04N 5/378

(52) U.S. Cl. CPC H04N 5/378; H04N 2101/00
USPC 348/302

(57) ABSTRACT

Solid-state imaging devices and electronic apparatuses are provided. More particularly, a solid-state imaging device that includes first and second substrates are provided. The first and second substrates are stacked on top of one another. The first substrate includes a pixel array and a peripheral circuit. The second substrate also includes a peripheral circuit. The device can be configured such that all resistors are formed in the second substrate, with no resistors being formed in the first substrate. Alternatively, the device can be configured such that all capacitors are formed in the second substrate, with no capacitors being formed in the first substrate. As yet another alternative, the second substrate can be configured such that it contains all resistors and capacitors of the peripheral circuits, with no resistors or capacitors being formed in the peripheral circuit of the first substrate.

### CROSS REFERENCE TO RELATED APPLICATIONS

This application claims the benefit of Japanese Priority Patent Application JP 2013-036303 filed Feb. 26, 2013, the entire contents of which are incorporated herein by reference.

### BACKGROUND

The present technology relates to a solid-state imaging device and an electronic apparatus, and particularly to a solid-state imaging device and an electronic apparatus that are such that the solid-state imaging device can be obtained in a small size at a low cost.

In the related art, there is known a solid-state imaging device in which a pixel array unit in which multiple unit pixels with each having a photo diode and others are arranged and a peripheral circuit for performing drive of the unit pixel or read-out of pixel data and so on are provided in one chip.

When designing such a solid-state imaging device, if making the chip smaller is given priority over the number of pixels, the more decreased the number of pixels, the greater an area occupied by the peripheral circuit or a pad in the chip compared to an area of the pixel array unit. For this reason, a lower limit value of a chip size is rate-controlled compared to areas of the peripheral circuit and the pad.

Then, a technology has been proposed in which the solid-state imaging device is made smaller by mounting a high-breakdown-voltage-transistor type circuit and the pixel array unit among the peripheral circuits in the first chip, mounting a low-breakdown-voltage-transistor type circuit among the peripheral circuits in the second chip, and laminating the two chips one on top of another (for example, refer to Japanese Unexamined Patent Application Publication No. 2011-159958).

### SUMMARY

Therefore, with the technology described above, it is difficult to realize making the solid-state imaging device smaller at a lower cost.

Specifically, the solid-state imaging device, if it has a laminated structure, can be made smaller, but when the peripheral circuit in the chip that makes up the solid-state imaging device, for example, in the first chip, includes a resistance element or a capacitance element, the number of masks necessary for manufacturing the first chip is increased. When this is done, a mask cost is increased and thus it is not possible to manufacture the solid-state imaging device at a low cost.

It is desirable to provide a small-sized solid-state imaging device that can be obtained at a low cost.

According to embodiments of the present disclosure, a solid-state imaging device is provided. The solid-state imaging device includes a first substrate with a pixel array unit in a peripheral circuit. The device further includes a second substrate that is stacked on the first substrate. The second substrate includes a peripheral circuit with at least one of a resistance element or a capacitance element. Moreover, the peripheral circuit of the second substrate at least one of: includes a resistance element and the peripheral circuit of the first substrate does not include a resistance element; includes a capacitance element and the peripheral circuit of the first substrate does not include a capacitance element; or includes both a resistance element and a capacitance element, and the peripheral circuit of the first substrate includes neither a resistance element nor a capacitance element.

In accordance with further embodiments of the present disclosure, an electronic apparatus is provided. The electronic apparatus includes an optical system, and a solid-state imaging device that receives light from the optical system. The solid-state imaging device includes a first substrate with a pixel array unit and a peripheral circuit. The solid-state imaging device further includes a second substrate that is stacked on the first substrate. The second substrate includes a peripheral circuit that itself includes at least one of a resistance element or a capacitance element. In addition, the peripheral circuit of the second substrate either: includes a resistance element and a peripheral circuit of the first substrate does not include a resistance element; includes a capacitance element and the peripheral circuit of the first substrate does not include a capacitance element; and includes both a resistance element and a capacitance element and the peripheral circuit of the first substrate includes neither a resistance element nor a capacitance element. The apparatus further includes a drive circuit that generates timing signals provided to the solid-state imaging device, and a signal processing circuit that performs signal processing on an output signal from the solid-state imaging device.

In accordance with still further embodiments of the present disclosure, an imaging device is provided. The imaging device includes a first substrate, and a second substrate, wherein the first substrate is stacked on the second substrate. A pixel array unit is included in the first substrate. A comparator is included in a first one of the first substrate and the second substrate. A reference supply unit is included in a second one of the first substrate and the second substrate. In addition, a bias generation circuit is included in the second one of the first substrate and the second one of the first substrate and the second substrate.

According to the embodiments of the present technology, the small-sized solid-state imaging device can be obtained at a low cost.

Additional features and advantages of embodiments of the present disclosure will become more readily apparent from the following description, particularly when taken together with the accompanying drawings.

### BRIEF DESCRIPTION OF THE DRAWINGS

FIG. 1 is a diagram for describing an outline of the present technology.

FIG. 2 is a diagram illustrating a detailed configuration example of a solid-state imaging device.

FIG. 3 is a diagram illustrating a detailed configuration example of the solid-state imaging device.

FIG. 4 is a diagram illustrating a detailed configuration example of the solid-state imaging device.

FIG. 5 is a diagram illustrating a detailed configuration example of the solid-state imaging device.

FIG. 6 is a diagram illustrating a configuration example of a bias generation circuit.

FIG. 7 is a diagram illustrating a configuration example of a negative electric potential generation circuit.

FIG. 8 is a diagram for describing a clock and a control signal that are supplied to the negative electric potential generation circuit.

FIG. 9 is a diagram illustrating a detailed configuration example of the solid-state imaging device.

FIG. 10 is a diagram illustrating a configuration example of the negative electric potential generation circuit.

FIG. 11 is a diagram illustrating a detailed configuration example of the solid-state imaging device.

FIG. 12 is a diagram illustrating a configuration example of the negative electric potential generation circuit.

FIG. 13 is a diagram for describing suppression of noise by a contact.

FIG. 14 is a diagram for describing suppression of the noise by a signal line.

FIG. 15 is a diagram illustrating a configuration example of an electronic apparatus.

### DETAILED DESCRIPTION

Embodiments to which the present technology is applied are described below referring to the drawings.

### First Embodiment

### Outline of the Present Technology

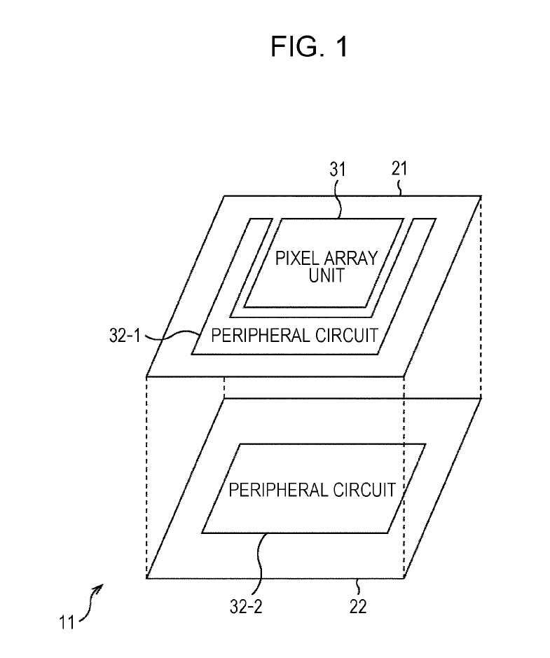

The solid-state imaging device to which the present technology is applied is made from a solid-state imaging element, such as a complementary metal oxide semiconductor (CMOS) image sensor, and has a laminated structure as illustrated in FIG. 1.

That is, a solid-state imaging device 11 has the laminated structure in which an upper chip or substrate 21, a CMOS image sensor (CIS) chip, is laminated or stacked on a lower chip or substrate 22, a logic chip. When capturing an image, the upper chip 21 is arranged at the side of an imaging lens. Furthermore, for example, the upper chip 21 is manufactured using a CIS process, and the lower chip 22 is manufactured using a high-speed logic process.

A pixel array unit 31 that is made from multiple unit pixels, each of which receives incident light from a photography object and photoelectricity-converts the light, and a peripheral circuit 32-1 that controls the drive of the solid-state imaging device 11 are provided on the upper chip 21 that makes up the solid-state imaging device 11.

Furthermore, a peripheral circuit 32-2 that controls the drive of the solid-state imaging device 11 is provided on the lower chip 22 that makes up the solid-state imaging device 11. For example, the peripheral circuit 32-1 and the peripheral circuit 32-2 control the drive of each unit pixel of the pixel array unit 31, or control various processing tasks that are performed in the solid-state imaging device 11, such as processing that reads out a signal that is obtained in each unit pixel, or processing that generates image data from the read-out signal. Moreover, the peripheral circuit 32-1 and the peripheral circuit 32-2, when it is not necessary to particularly distinguish between them, are collectively referred to as a peripheral circuit 32.

Incidentally, in a case where an area of the pixel array unit 31 is greater than a total of areas of all the peripheral circuits 32, if only the pixel array unit 31 is arranged in the upper chip 21 and the peripheral circuits 32 are arranged in the lower chip 22, a floor plan of the chip for minimizing the solid-state imaging device 11 can be realized.

On the other hand, in a case where the area of the pixel array unit 31 is smaller than the total of areas of all the peripheral circuits 32, if only the pixel array unit 31 is arranged in the upper chip 21 and the peripheral circuits 32 are arranged in the lower chip 22, a region into which none is integrated occurs in the upper chip 21. In summary, the region of the upper chip 21 remains unoccupied.

Accordingly, according to the present technology, making the solid-state imaging device 11 smaller can be realized by arranging not only the pixel array unit 31 but also the peripheral circuit 32-1, one part of the peripheral circuit 32, on the upper chip 21, as illustrated in the upper portion of FIG. 1.

Furthermore, in the solid-state imaging device 11, the peripheral circuit 32-1 that is arranged in the upper chip 21 is a circuit that include at least neither a resistance element nor a capacitance element, and the peripheral circuit 32-2 that is arranged in the lower chip 22 is a circuit in which the resistance element or the capacitance element is provided when necessary. In summary, in the solid-state imaging device 11, at least either the resistance elements or the capacitance elements that are provided within the peripheral circuit 32 are all formed in the lower chip 22.

For example, in a case of manufacturing the upper chip 21, when the peripheral circuit 32-1 in the upper chip 21 includes the resistance element or the capacitance element, the number of masks that are necessary for manufacturing the upper chip 21 is increased and thus a manufacturing cost of the upper chip 21 is increased.

Accordingly, according to the present technology, when considering a mask cost and the like, the manufacturing cost of the upper chip 21 is suppressed by setting a circuit not including the resistance element to be the peripheral circuit 32-1 or by setting a circuit not including the capacitance element to be the peripheral circuit 32-1. Accordingly, the solid-state imaging device 11 can be manufactured at a lower cost.

Configuration Example of Solid-State Imaging Device

Next, a configuration example of the solid-state imaging device 11 described above is described in more detail.

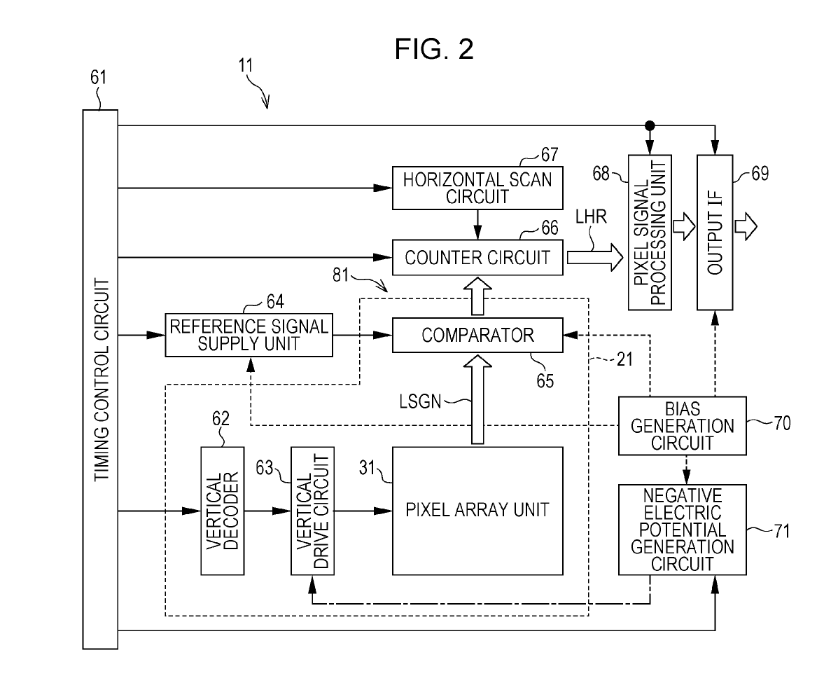

For example, the solid-state imaging device 11 is configured as illustrated in detail in FIG. 2. Moreover, in FIG. 2, like reference numerals are given to like parts that correspond to those in FIG. 1, and descriptions of the like parts are appropriately omitted.

The solid-state imaging device 11 described in FIG. 2 is configured from a pixel array unit 31, a timing control circuit 61, a vertical decoder 62, a vertical drive circuit 63, a reference signal supply unit 64, a comparator 65, a counter circuit 66, a horizontal scan circuit 67, a pixel signal processing unit 68, an output interface (IF) 69, a bias generation circuit 70, and a negative electric potential generation circuit 71.

In this example, circuits each of which does not include a low-breakdown-voltage transistor and the resistance element and is made from a high-breakdown-voltage transistor are integrated as the peripheral circuits 32-1 into the upper chip 21. That is, the pixel array unit 31, and the vertical decoder 62, and the vertical drive circuit 63 and the comparator 65 as the peripheral circuits 32-1 are integrated into the upper chip 21. For example, the comparator 65 is configured in such a manner as not to include the resistance element.

At this point, the high-breakdown-voltage transistor is a transistor in which a thickness of a gate oxide film, a gate insulating film, is set to be greater than that of a normal MOS transistor, and which can operate without problems at a high voltage. Furthermore, the low-breakdown-voltage transistor is a transistor in which a thickness of the gate insulating film is set to be the same as that of the normal MOS transistor or less, and which can operate at high speed at a low voltage and is lower in breakdown voltage than the high-breakdown-voltage transistor.

For example, when both of the high-breakdown-voltage transistor and the low-breakdown-voltage transistor are integrated into the upper chip 21, the number of masks is increased when manufacturing the upper chip 21 and the mask cost is increased. For this reason, from a perspective of the manufacturing cost, it is preferable that the high-breakdown-voltage transistor and the low-breakdown-voltage transistor be separately arranged in the upper chip 21 and lower chip 22, respectively. Furthermore, it is preferable that an element, high in breakdown voltage, be arranged in the vicinity of the pixel array unit 31, because the pixel array unit 31 provided in the upper chip 21 is driven at a high voltage.

Accordingly, in the solid-state imaging device 11, the manufacturing of the solid-state imaging device 11 at a low cost is accomplished by arranging the peripheral circuit 32 including the high-breakdown-voltage transistor in the upper chip 21 and by arranging the peripheral circuit 32 including the low-breakdown-voltage transistor in the lower chip 22.

Furthermore, in the solid-state imaging device 11, the timing control circuit 61, the reference signal supply unit 64, the counter circuit 66, the horizontal scan circuit 67, the pixel signal processing unit 68, the output IF 69, the bias generation circuit 70, and the negative electric potential generation circuit 71 are integrated as the peripheral circuits 32-2 into the lower chip 22.

For example, the timing control circuit 61, the counter circuit 66, the horizontal scan circuit 67, the pixel signal processing unit 68, and the output IF 69 are a circuit in which the low-breakdown-voltage transistor that has a higher performance than the high-breakdown-voltage transistor is preferably used. Furthermore, the reference signal supply unit 64, the bias generation circuit 70, and the negative electric potential generation circuit 71 are circuits that include a resistance element.

In FIG. 2, the solid-state imaging device 11 has the pixel array unit 31 in which unit pixels not illustrated, each including a photoelectric transducer, are two-dimensionally arranged, in rows and columns, that is, in the shape of a matrix. Furthermore, the comparator 65 and the counter circuit 66 as a circuit that makes up a column processing unit 81 are provided in the solid-state imaging device 11.

In the solid-state imaging device 11, the timing control circuit 61 generates a clock signal, a control signal, or the like that serves as an operation reference for the vertical drive circuit 63, the column processing unit 81, the reference signal supply unit 64, the negative electric potential generation circuit 71, the horizontal scan circuit 67, and the like, based on a master clock.

Furthermore, a peripheral drive mechanism that drive-controls each unit pixel of the pixel array unit 31, or an analog mechanism, that is, the vertical drive circuit 63, the comparator 65 of the column processing unit 81, and the like are integrated into the upper chip 21 in the same manner as the pixel array unit 31. On the other hand, the timing control circuit 61, the reference signal supply unit 64, the pixel signal processing unit 68, and the counter circuit 66 of the column processing unit 81, and the horizontal scan circuit 67 are integrated into the lower chip 22, a separate semiconductor substrate from the upper chip 21.

The unit pixel provided in the pixel array unit 31, although its illustration is omitted, has a photoelectric transducer, such as a photo diode. In addition to the photoelectric transducer, the unit pixel has, for example, a transmission transistor that transmits an electric charge, which is obtained by performing photoelectric conversion in the photoelectric transducer, to a floating diffusion unit (hereinafter referred to as an FD unit).

For the unit pixel, a three-transistor configuration can be applied that, in addition to the transmission transistor, includes a reset transistor that controls an electric potential of the FD unit and an amplification transistor that outputs a signal that depends on the electric potential of the FD unit. Alternatively, for the unit pixel, a four-transistor configuration and the like can be employed that separately includes a selection transistor in order to further perform pixel selection.

In the pixel array unit 31, unit pixels in m rows and n columns are two-dimensionally arranged, and with respect to the m-row and n-column arrangement, a row control line is provided to each row for wiring and a column signal line is provided to each column for wiring. Each end of the row control line is connected to each output terminal that depends on each row in the vertical drive circuit 63. The vertical drive circuit 63 is configured from shift registers and the like, and performs row address control and row scan control on the pixel array unit 31 via the row control line.

For the transmission transistor and the selection transistor of the unit pixel, it is recommended that a negative voltage be applied to a gate at an off time. With the transmission transistor, an occurrence of a dark signal can be prevented, and with the selection transistor, a leakage current can be prevented. The negative voltage is generated in the negative electric potential generation circuit 71 that functions as a charge pump circuit, and is supplied to the transmission transistor and the selection transistor within the pixel array unit 31 via the vertical drive circuit 63.

The bias generation circuit 70 is a circuit that generates a reference voltage and a reference current that is minutely influenced by a disturbance such as a temperature or a power source voltage. The reference voltage and the reference current, which are generated in the bias generation circuit 70, are supplied to the comparator 65, the reference signal supply unit 64, the negative electric potential generation circuit 71, and the output IF 69.

The column processing unit 81 has an analog digital converter (ADC) that is provided, for example, to every column in the pixel array unit 31, that is, to every vertical signal line LSGN, converts an analog signal that is output from each unit pixel of the pixel array unit 31 to every column into a digital signal and outputs the result of the conversion.

The reference signal supply unit 64 has, for example, a digital analog converter (DAC) in which a level changes in an inclined form as time goes by, and which generates a reference voltage Vref in a so-called ramp waveform. Moreover, the unit that generates the reference voltage Vref in the ramp waveform is not limited to the DAC.

Under the control of the control signal given by the timing control circuit 61, the DAC of the reference signal supply unit 64 generates the reference voltage Vref in the ramp waveform, based on a clock given by the timing control circuit 61 and supplies the generated reference voltage Vref to the ADC of the column processing unit 81.

Moreover, each ADC of the column processing unit 81 has a configuration that can selectively perform AD conversion operations that correspond to an operational mode of a normal frame rate mode in a progressive scan method in which the information in all the unit pixels is read out and an operational mode of a high-speed frame rate mode, respectively.

At this point, the high-speed the frame rate mode is an operational mode in which an exposure time of the unit pixel is set to 1/N and increases a frame rate to N times as much, for example, to two times as much, compared to a case of the normal frame rate mode. Switching to this operational mode is executed under the control of the control signal given by the timing control circuit 61. Furthermore, an external system controller (not illustrated) gives the timing control circuit 61 instruction information for switching between the operational mode of the normal frame rate mode and the operational mode of the high-speed frame rate mode.

Furthermore, all the ADCs of the column processing unit 81 have the same configuration, and the ADC is made from the comparator 65 and the counter circuit 66. For example, the ADC has a up/down counter, a transmission switch, and a memory device.

The comparator 65 compares a signal voltage of the vertical signal line LSGN that depends on a signal that is output from each unit pixel in the n-th column in the pixel array unit 31 and the reference voltage Vref in the ramp waveform that is supplied from the reference signal supply unit 64.

In the comparator 65, for example, when the reference voltage Vref is greater than the signal voltage, an output Vco is at an “H” level, and when the reference voltage Vref is the signal voltage or less, the output Vco is at an “L” level.

The counter circuit 66, that is, the up/down counter, is an asynchronous counter, and the control signal from the timing control circuit 61 is supplied to the counter circuit 66. A clock is supplied to the DAC of the reference signal supply unit 64, and at the same time, a clock from the timing control circuit 61 is given.

The counter circuit 66 is synchronized with the clock from the timing control circuit 61, and by performing down-counting or up-counting, measures a comparison period-of-time from a start of a comparison operation in the comparator to an end of the comparison operation.

In this manner, the analog signal that is supplied from each unit pixel of the pixel array unit 31 to every column via the column signal line is converted by each operation of the comparator 65 and the counter circuit 66, the up/down counter, into the N-bit digital signal and is stored in the memory device.

The horizontal scan circuit 67 is configured from the shift register and the like and performs column address control and column scan control on the ADC in the column processing unit 81.

Under the control of the horizontal scan circuit 67, the N-bit digital signal that is AD-converted in each of the ADCs is read out one after another by a horizontal signal line LHR and is output as imaging data to the pixel signal processing unit 68 via the horizontal signal line LHR.

The pixel signal processing unit 68 is a circuit that performs various signal processing tasks on the imaging data and is configured to include an image signal processor (ISP), a microprocessor, a memory circuit and the like. The imaging data on which the signal processing is performed in the pixel signal processing unit 68 is output to the outside via the output IF 69.

According to the present embodiment, in the comparator 65 mounted on the upper chip 21, a comparison is made between the signal voltage of the vertical signal line LSGN that depends on the signal that is output from each unit pixel and the reference voltage Vref in the ramp waveform that is supplied from the reference signal supply unit 64. Then, based on the result of the comparison, the comparison period-of-time from the start of the comparison operation to the end of the comparison operation is measured by the counter circuit 66 mounted on the lower chip 22.

According to the present technology as described above, the circuits each of which does not include the resistance element are integrated into the upper chip 21 and the circuits each of which includes the resistance element are integrated into the lower chip 22, and thus the small-sized solid-state imaging device 11 can be obtained at a low cost.

### Second Embodiment

### Configuration Example of Solid-State Imaging Device

Furthermore, the case where the circuits each of which does not include the resistance element are set to be the peripheral circuits 32-1 that are integrated into the upper chip 21 is described above, but the circuits each of which does not include the capacitance element may be set to be the peripheral circuits 32-1.

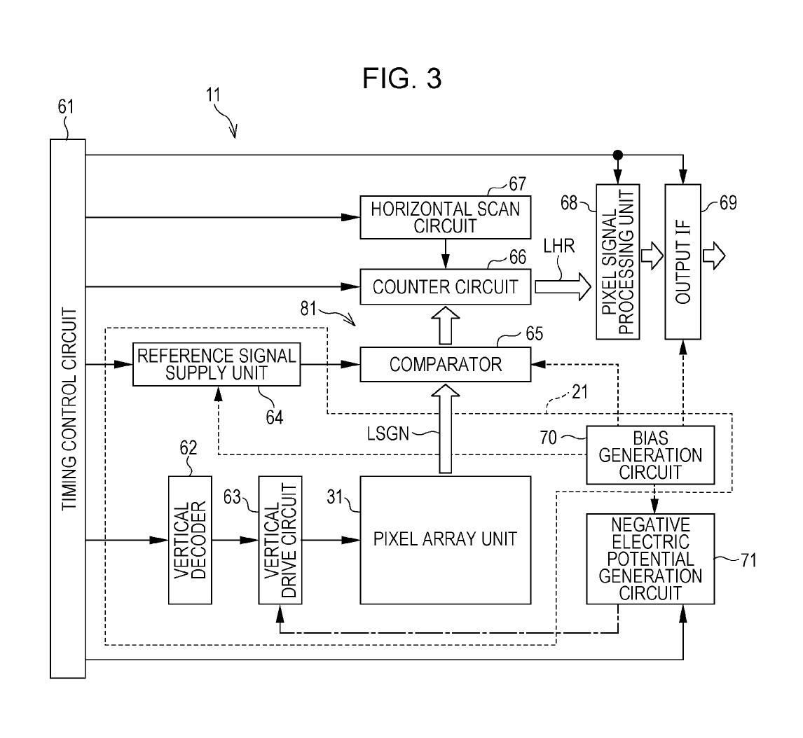

In such a case, for example, the solid-state imaging device 11 is configured as illustrated in FIG. 3. Moreover, in FIG. 3, like reference numerals are given to like parts that correspond to those in FIG. 2, and descriptions of the like parts are appropriately omitted.

According to a floor plan of the solid-state imaging device 11 described in FIG. 3, the circuits each of which does not include the low-breakdown-voltage transistor and the capacitance element are integrated as the peripheral circuits 32-1 into the upper chip 21. In this example, the comparator 65 and the negative electric potential generation circuit 71 that include the capacitance element are integrated into the lower chip 22, and the reference signal supply unit 64 and the bias generation circuit 70 that do not include the capacitance element are integrated into the upper chip 21.

That is, the pixel array unit 31, and the vertical decoder 62, the vertical drive circuit 63, the reference signal supply unit 64 and the bias generation circuit 70 as the peripheral circuits 32-1 are integrated into the upper chip 21.

Furthermore, the timing control circuit 61, the comparator 65, the counter circuit 66, the horizontal scan circuit 67, the pixel signal processing unit 68, the output IF 69, and the negative electric potential generation circuit 71 are integrated as the peripheral circuits 32-2 into the lower chip 22.

Because the peripheral circuit 32 is provided in each of the upper chip 21 and the lower chip 22 also in the solid-state imaging device 11 illustrated in FIG. 3, making the solid-state imaging device 11 smaller can be accomplished by a circuit arrangement that has a high degree of freedom. Furthermore, in the solid-state imaging device 11, all the peripheral circuits 32 each of which includes the capacitance element, which are a cause for increasing the mask cost, are arranged in the lower chip 22, and thus the manufacturing cost of the solid-state imaging device 11 can be further suppressed.

### Third Embodiment

### Configuration Example of Solid-State Imaging Device

Furthermore, the case where the circuits each of which includes neither the resistance element nor the capacitance element are set to be the peripheral circuits 32-1 that are integrated into the upper chip 21 is described above, but the circuits each of which includes neither the resistance element nor the capacitance element may be set to be the peripheral circuits 32-1.

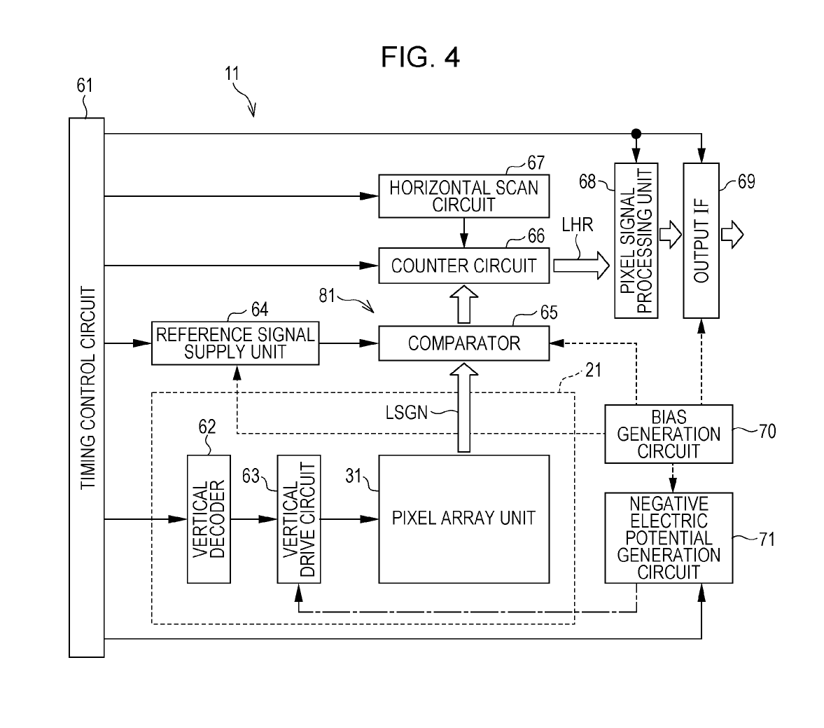

In such a case, for example, the solid-state imaging device 11 is configured as illustrated in FIG. 4. Moreover, in FIG. 4, like reference numerals are given to like parts that correspond to those in FIG. 2, and descriptions of the like parts are appropriately omitted.

According to a floor plan of the solid-state imaging device 11 described in FIG. 4, the circuits each of which does not include the low-breakdown-voltage transistor, the resistance element, and the capacitance element are integrated as the peripheral circuits 32-1 into the upper chip 21. In this example, the comparator 65, the reference signal supply unit 64, the bias generation circuit 70, and the negative electric potential generation circuit 71, each of which includes the resistance element or the capacitance element are integrated into the lower chip 22.

That is, the pixel array unit 31, and the vertical decoder 62 and the vertical drive circuit 63 as the peripheral circuits 32-1 are integrated into the upper chip 21. Furthermore, the timing control circuit 61, the reference signal supply unit 64, the comparator 65, the counter circuit 66, the horizontal scan circuit 67, the pixel signal processing unit 68, the output IF 69, the bias generation circuit 70, and the negative electric potential generation circuit 71 are integrated as the peripheral circuits 32-2 into the lower chip 22.

Because also in the solid-state imaging device 11 illustrated in FIG. 4, the peripheral circuit 32 is provided in each of the lower chip 22 and the upper chip 21 that is laminated on the lower chip 22, making the solid-state imaging device 11 smaller can be accomplished. Furthermore, in the solid-state imaging device 11, all the peripheral circuits 32 each of which includes the resistance element or the capacitance element, which are a cause for increasing the mask cost, are arranged in the lower chip 22, and thus the manufacturing cost of the solid-state imaging device 11 can be further suppressed.

### Fourth Embodiment

### Configuration Example of Solid-State Imaging Device

Furthermore, according to the first embodiment described above, the example in which the circuit that does not include the resistance element is set to be the peripheral circuit 32-1 is described, but one part of one circuit as the peripheral circuit 32 may be integrated into the upper chip 21 and the remaining parts including the resistance element may be integrated into the lower chip 22.

For example, the circuits each of which does not include the low-breakdown-voltage transistor and the resistance element are integrated as the peripheral circuit 32-1 into the upper chip 21, and a predetermined circuit that realizes one function is divided into one part that includes the resistance element and the other part that does not include the resistance element and the one part and the other part are integrated into the upper chip 21 and the lower chip 22, respectively.

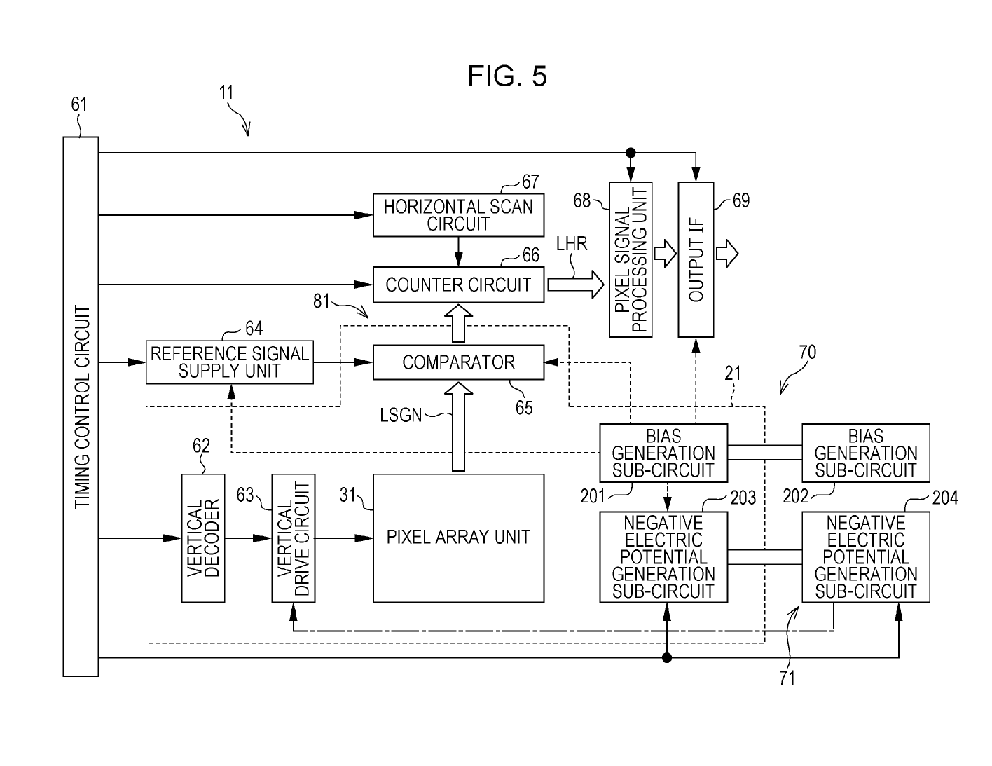

If each circuit is arranged according to this floor plan, for example, the solid-state imaging device 11 is configured as illustrated in FIG. 5. Moreover, in FIG. 5, like reference numerals are given to like parts that correspond to those in FIG. 2, and descriptions of the like parts are appropriately omitted.

According to the floor plan of the solid-state imaging device 11 described in FIG. 5, one bias generation circuit 70 that realizes a function of outputting the reference current to a predetermined circuit is divided into two circuits, a bias generation sub-circuit 201 and a bias generation sub-circuit 202, and the two circuits are integrated into the upper chip 21 and the lower chip 22, respectively.

At this point, the bias generation sub-circuit 201 is a circuit that is made from elements that are different from the low-breakdown-voltage transistor and the resistance element, among elements making up the bias generation circuit 70, and is arranged in the upper chip 21. Furthermore, the bias generation sub-circuit 202 is a circuit that is made from several elements that include at least the resistance element, among the elements making up the bias generation circuit 70, and is arranged in the lower chip 22.

Then, the bias generation sub-circuit 201 and the bias generation sub-circuit 202 are electrically connected to each other via a contact provided between the upper chip 21 and the lower chip 22, and the analog signal is transferred and received between the bias generation sub-circuit 201 and the bias generation sub-circuit 202.

Similarly, in the solid-state imaging device 11, one negative electric potential generation circuit 71 that functions as a charge pump is divided into two circuits, a negative electric potential generation sub-circuit 203 and a negative electric potential generation sub-circuit 204, and the two circuits are integrated into the upper chip 21 and the lower chip 22, respectively.

At this point, the negative electric potential generation sub-circuit 203 is a circuit that is made from elements that are different from the low-breakdown-voltage transistor and the resistance element, among the elements making up the negative electric potential generation circuit 71, and is arranged in the upper chip 21. Furthermore, the negative electric potential generation sub-circuit 204 is a circuit that is made from several elements that include at least the resistance element, among the elements making up the negative electric potential generation circuit 71, and is arranged in the lower chip 22.

Then, the negative electric potential generation sub-circuit 203 and the negative electric potential generation sub-circuit 204 are electrically connected to each other via the contact provided between the upper chip 21 and the lower chip 22, and the analog signal is transmitted and received between the negative electric potential generation sub-circuit 203 and the negative electric potential generation sub-circuit 204.

Furthermore, in this example, the pixel array unit 31, and the vertical decoder 62, the vertical drive circuit 63, the comparator 65, the bias generation sub-circuit 201, and the negative electric potential generation sub-circuit 203 as the peripheral circuits 32-1 are integrated into the upper chip 21.

Furthermore, the timing control circuit 61, the reference signal supply unit 64, the counter circuit 66, the horizontal scan circuit 67, the pixel signal processing unit 68, the output IF 69, the bias generation sub-circuit 202, and the negative electric potential generation sub-circuit 204 are integrated as the peripheral circuits 32-2 into the lower chip 22.

Because also in the solid-state imaging device 11 illustrated in FIG. 5, the peripheral circuit 32 is provided in each of the lower chip 22 and the upper chip 21 that is laminated on the lower chip 22, making the solid-state imaging device 11 smaller can be accomplished by the circuit arrangement that has the high degree of freedom.

Particularly, one circuit such as the bias generation circuit 70 or the negative electric potential generation circuit 71 is divided into two sub-circuits, and the two sub-circuits are arranged in the upper chip 21 and the lower chip 22, respectively. Thus, the floor plan for the high degree of freedom can be further accomplished. That is, for example, in the peripheral circuit 32, the sub-circuit that is arranged in the upper chip 21 and the sub-circuit that is arranged in the lower chip 22 can be determined with high degree of freedom. Accordingly, optimization of a chip size of the solid-state imaging device 11 can be more simply performed, and further making the solid-state imaging device 11 smaller can be accomplished.

Furthermore, in the solid-state imaging device 11, all the peripheral circuits 32 each of which includes the resistance element, which are a cause for increasing the mask cost, are arranged in the lower chip 22, and thus the manufacturing cost of the solid-state imaging device 11 can be further suppressed.

Configuration Example of Bias Circuit

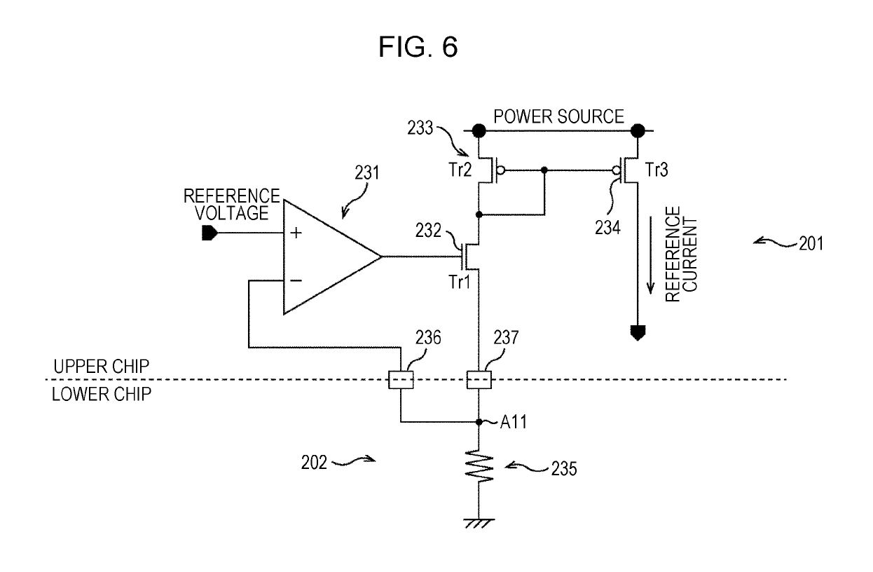

Moreover, the bias generation circuit 70 in the solid-state imaging device 11 described in FIG. 5 is described as being divided into the bias generation sub-circuit 201 and the bias generation sub-circuit 202, but for example, in this case, the bias generation circuit 70 is configured as illustrated in more detail in FIG. 6. Moreover, in FIG. 6, like reference numerals are given to like parts that correspond to those in FIG. 5, and descriptions of the like parts are appropriately omitted.

In FIG. 6, above a dotted line is a region of the upper chip 21 and below the dotted line is a region of the lower chip 22.

In this example, the bias generation sub-circuit 201 is configured from an amplifier 231, a transistor 232, the transistor 233, and the transistor 234. Furthermore, the bias generation sub-circuit 202 is configured from the resistance element 235, and the bias generation sub-circuit 201 and the bias generation sub-circuit 202 are electrically connected to each other via a contact 236 and a contact 237.

The reference voltage is applied to a positive-side input terminal of the amplifier 231 and a negative-side input terminal of the amplifier 231 is connected to the resistance element 235 via the contact 236. Furthermore, an output terminal of the amplifier 231 is connected to a gate of the transistor 232.

One end of the transistor 232 is connected to the resistance element 235 via the contact 237, and the other end of the transistor 232 is connected to the transistor 233 and the transistor 234. Furthermore, a gate of the transistor 233 and a gate of the transistor 234 are connected to each other.

Moreover, the transistor 233 and the transistor 234 are connected also to a power source, and one end of the resistance element 235, which is opposite to the other end to which the contact 236 and the contact 237 are connected, is connected to ground.

In this manner, the bias generation sub-circuit 201 is configured from an element that is different from the low-breakdown-voltage transistor or the resistance element, and the bias generation sub-circuit 202 is configured from the resistance element.

At the node A11 to which the amplifier 231, the transistor 232, and the resistance element 235 are connected, the bias generation circuit 70 is forced to have the same electric potential as the reference voltage to the node A11 to which the amplifier 231, the transistor 232, and the resistance element 235 are connected.

When this is done, an electric potential of the node A11, that is, a current determined from the reference voltage and the resistance element 235, flows through the transistor 232 and the transistor 233. With a current mirror configuration, the current through the transistor 233 is mirrored in the transistor 234. The mirrored current is supplied as the reference current from the transistor 234 to the reference signal supply unit 64, the comparator 65, the output IF 69, and the negative electric potential generation sub-circuit 203.

Configuration Example of Negative Electric Potential Generation Circuit

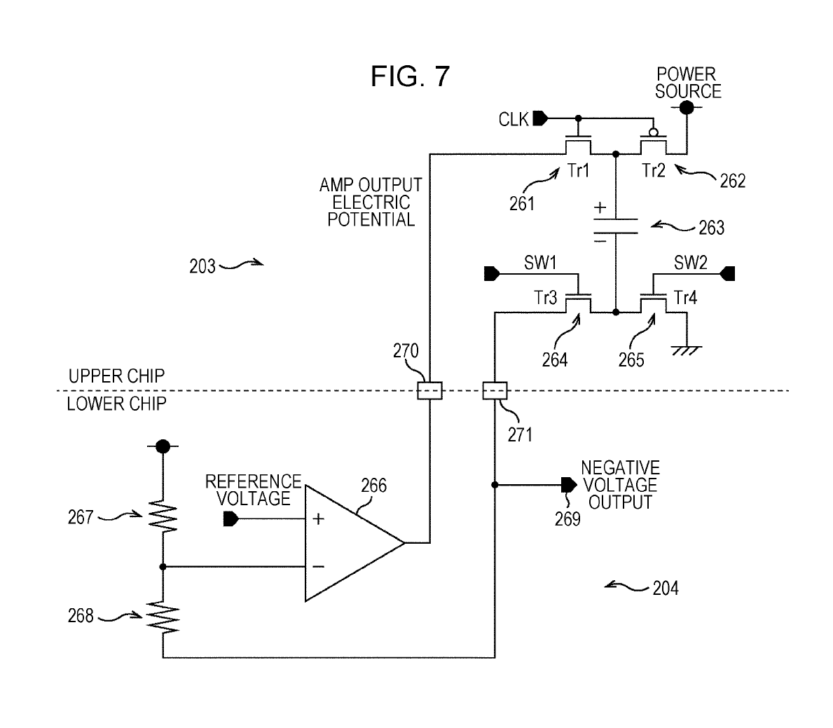

Furthermore, the negative electric potential generation circuit 71 in the solid-state imaging device 11 illustrated in FIG. 5, is described as being divided into the negative electric potential generation sub-circuit 203 and the negative electric potential generation sub-circuit 204, but for example, in this case, the negative electric potential generation circuit 71 is configured as illustrated in more detail in FIG. 7. Moreover, in FIG. 7, like reference numerals are given to like parts that correspond to those in FIG. 5, and descriptions of the like parts appropriately omitted.

In FIG. 7, above a dotted line is a region of the upper chip 21 and below the dotted line is a region of the lower chip 22.

In this example, the negative electric potential generation sub-circuit 203 is configured from a transistor 261, a transistor 262, a pumping capacitor 263, a transistor 264, and a transistor 265. Furthermore, the negative electric potential generation sub-circuit 204 is configured from an amplifier 266, a resistance element 267, a resistance element 268, and a negative voltage output node 269. Then, the negative electric potential generation sub-circuit 203 and the negative electric potential generation sub-circuit 204 are electrically connected to each other via a contact 270 and a contact 271.

One end of the transistor 261 is connected to an output terminal of the amplifier 266 via the contact 270, and the other end of the transistor 261 is connected to the transistor 262 and the pumping capacitor 263. Furthermore, one end of the transistor 262, which is opposite to the other end to which the transistor 261 and the pumping capacitor 263 are connected, is connected to the power source. Moreover, the clock from the timing control circuit 61 is supplied to gates of the transistor 261 and the transistor 262.

One electrode that makes up the pumping capacitor 263 is connected to the transistor 261 and the transistor 262, and the other electrode that makes up the pumping capacitor 263 is connected to the transistor 264 and the transistor 265. Furthermore, one end of the transistor 264, which is opposite to the other end which is connected to the pumping capacitor 263, is connected to the negative voltage output node 269 and the resistance element 268 via the contact 271. One end of the transistor 265, which is opposite to the other end which is connected to the pumping capacitor 263 is connected to the ground.

Furthermore, the reference voltage is applied to a positive-side input terminal of the amplifier 266 and a negative-side input terminal of the amplifier 266 is connected to the resistance element 267 and the resistance element 268. One end of the resistance element 267 is connected to the power source, and the other end is connected to the resistance element 268 and the negative-side input terminal of the amplifier 266. One end of the resistance element 268 is connected to the negative voltage output node 269 and the transistor 264, and the other end is connected to the resistance element 267 and the negative-side input terminal of the amplifier 266.

In this manner, the negative electric potential generation sub-circuit 203 is configured from the elements that are different from the low-breakdown-voltage transistor or the resistance element, and the negative electric potential generation sub-circuit 204 is configured from several elements that include the resistance element. In this example, because the pumping capacitor 263 is large in size, when the pumping capacitor 263 is arranged in the upper chip 21, a large circuit division effect is obtained.

Next, operation of the negative electric potential generation circuit 71 illustrated in FIG. 7 is described.

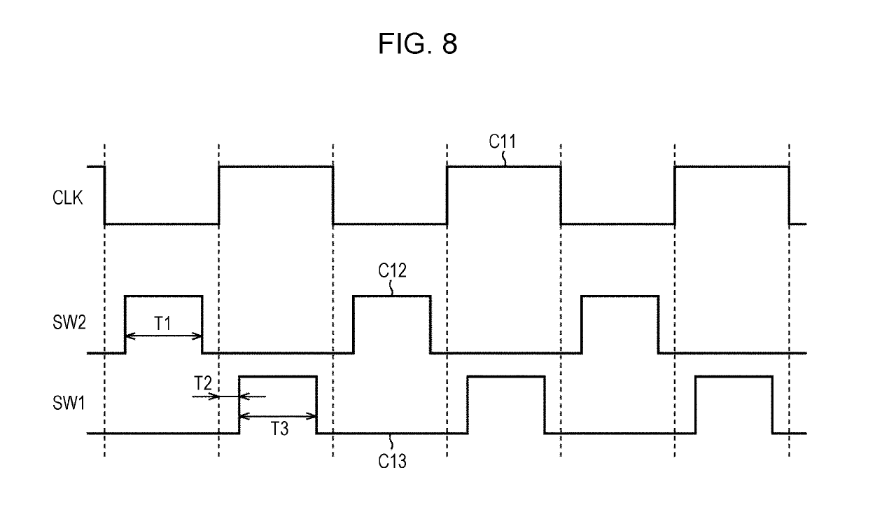

For example, a signal indicated by a square wave C11, a square wave C12, and a square wave C13 illustrated in FIG. 8 is supplied to gates of the transistor 262 and the transistor 261 in the negative electric potential generation circuit 71, a gate of the transistor 265, and a gate of the transistor 264. Moreover, in FIG. 8, the longitudinal direction indicates a voltage and the transverse direction indicates a time.

In FIG. 8, a clock CLK indicated by the square wave C11 is supplied from the timing control circuit 61 to gates of the transistor 261 and the transistor 262. Furthermore, a control signal SW2 indicated by the square wave C12 and the control signal SW1 indicated by the square wave C13 are supplied from the timing control circuit 61 to gates of the transistor 265 and the transistor 264, respectively.

In this example, during a period of time T1, the transistor 262 is turned on with the clock CLK indicated by the square wave C11 and the transistor 265 is turned on with the control signal SW2 indicated by the square wave C12. Accordingly, the transistor 262 and the transistor 265 are in a conduction state, and the transistor 261 and the transistor 264 are in a non-conduction state.

At this time, a power source voltage is applied to a positive-side electrode of the pumping capacitor 263 via the transistor 262, and a ground voltage is applied to a negative-side electrode of the pumping capacitor 263 via the transistor 265. Then, an electric charge that depends on a difference in electric potential between the power source and the ground is accumulated in the pumping capacitor 263.

Furthermore, during a period of time T2 that follows the period of time T1, the transistor 261 is turned on with the clock CLK indicated by the square wave C11. Accordingly, the transistor 261 is in the conduction state, and the transistor 262, the transistor 264, and the transistor 265 are in the non-conduction state.

At this time, a voltage of the output terminal of the amplifier 266 is applied to the positive-side electrode of the pumping capacitor 263, and thus an electric potential of the positive-side electrode is an output electric potential of the amplifier 266 and floating is applied to the negative-side electrode of the pumping capacitor 263. At this point, because the output electric potential of the amplifier 266 is lower than an electric potential of the power source, a negative electric charge occurs at the negative-side electrode of the pumping capacitor 263.

Moreover, during a period of time T3, the transistor 261 is turned on with the clock CLK indicated by the square wave C11, and the transistor 264 is turned on with the control signal SW1 indicated by the square wave C13. Accordingly, the transistor 261 and the transistor 264 are in the conduction state, and the transistor 262 and the transistor 265 are in a non-conduction state.

At this time, the negative electric charge accumulated in the negative-side electrode of the pumping capacitor 263 is supplied to the negative voltage output node 269. Accordingly, the negative voltage is applied by the negative voltage output node 269 to the vertical drive circuit 63. Then, subsequently, the operation described above is repeatedly performed and a negative electric potential generation operation is performed.

In the negative electric potential generation circuit 71, in order to stabilize a negative electric potential with a target value, an electric potential, which results from pressure-dividing the electric power and the negative electric potential with the resistance element 267 and the resistance element 268, is fed back to the negative-side input terminal of the amplifier 266.

If the negative voltage output node 269 is in such a state that its electric potential is higher than the target negative electric potential, an electric potential that is close to an electric potential of the ground is taken as the output electric potential of the amplifier 266 and an ability to generate the negative electric potential is increased. If the negative voltage output node 269 is in such a state that its electric potential is lower than the target negative electric potential, an electric potential that is close to that of the power source is taken as the output electric potential of the amplifier 266 and the ability to generate the negative electric potential is decreased. With this mechanism, the negative electric potential is close to a target value and is stabilized.

### Fifth Embodiment

### Configuration Example of Solid-State Imaging Device

Furthermore, according to the second embodiment described above, the example in which the circuit that does not include the capacitance element is set to be the peripheral circuit 32-1 is described, but one part of one circuit as the peripheral circuit 32 may be integrated into the upper chip 21 and the remaining parts including the capacitance element may be integrated into the lower chip 22.

For example, circuits each of which does not include the low-breakdown-voltage transistor and the capacitance element are integrated as the peripheral circuit 32-1 into the upper chip 21, and a predetermined circuit that realizes one function is divided into a part that includes the capacitance element and a part that does not include the capacitance element and the two parts are integrated into the upper chip 21 and the lower chip 22, respectively.

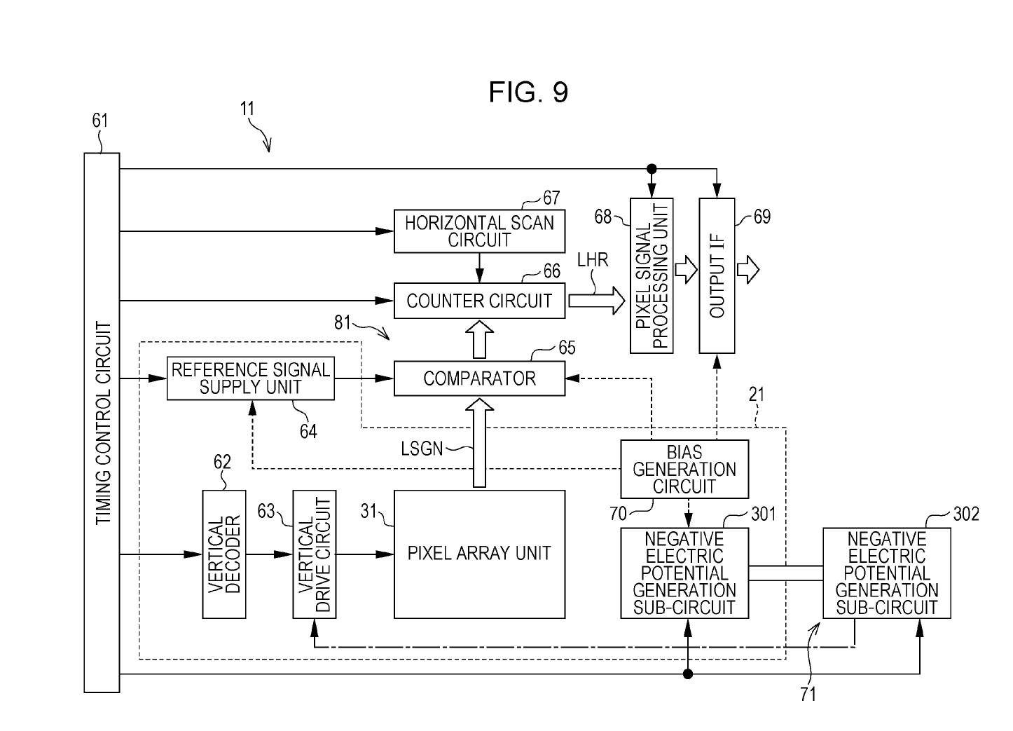

If each circuit is arranged according to this floor plan, for example, the solid-state imaging device 11 is configured as illustrated in FIG. 9. Moreover, in FIG. 9, like reference numerals are given to like parts that correspond to those in FIG. 2, and descriptions of the like parts are appropriately omitted.

According to a floor plan of the solid-state imaging device 11 illustrated in FIG. 9, one negative electric potential generation circuit 71 that functions as the charge pump is divided into two circuits, a negative electric potential generation sub-circuit 301 and a negative electric potential generation sub-circuit 302, and the two circuits are integrated into the upper chip 21 and the lower chip 22, respectively.

At this point, the negative electric potential generation sub-circuit 301 is a circuit that is made from elements that are different from the low-breakdown-voltage transistor and the capacitance element, among the elements making up the negative electric potential generation circuit 71, and is arranged in the upper chip 21. Furthermore, the negative electric potential generation sub-circuit 302 is a circuit that is made from several elements that include at least the capacitance element, among the elements making up the negative electric potential generation circuit 71, and is arranged in the lower chip 22.

Then, the negative electric potential generation sub-circuit 301 and the negative electric potential generation sub-circuit 302 are electrically connected to each other via the contact provided between the upper chip 21 and the lower chip 22, and the analog signal is transmitted and received between the negative electric potential generation sub-circuit 301 and the negative electric potential generation sub-circuit 302.

Furthermore, in this example, the pixel array unit 31, and the vertical decoder 62, the vertical drive circuit 63, the reference signal supply unit 64, the bias generation circuit 70, and the negative electric potential generation sub-circuit 301 as the peripheral circuits 32-1 are integrated into the upper chip 21.

Moreover, the timing control circuit 61, the comparator 65, the counter circuit 66, the horizontal scan circuit 67, the pixel signal processing unit 68, the output IF 69, and the negative electric potential generation sub-circuit 302 are integrated as the peripheral circuits 32-2 into the lower chip 22.

Because also in the solid-state imaging device 11 illustrated in FIG. 9, the peripheral circuit 32 is provided in each of the lower chip 22 and the upper chip 21 that is laminated on the lower chip 22, making the solid-state imaging device 11 smaller can be accomplished by the circuit arrangement that has the high degree of freedom. Particularly, the negative electric potential generation circuit 71 is divided into two sub-circuits, and the two sub-circuits are arranged in the upper chip 21 and the lower chip 22, respectively. Thus, the floor plan for the high degree of freedom can be further accomplished. Accordingly, the optimization of the chip size of the solid-state imaging device 11 can be more simply performed, and further making the solid-state imaging device 11 smaller can be accomplished.

Furthermore, in the solid-state imaging device 11, all the peripheral circuits 32 each of which includes the capacitance element, which are a cause for increasing the mask cost, are arranged in the lower chip 22, and thus the manufacturing cost of the solid-state imaging device 11 can be further suppressed.

Configuration Example of Negative Electric Potential Generation Circuit

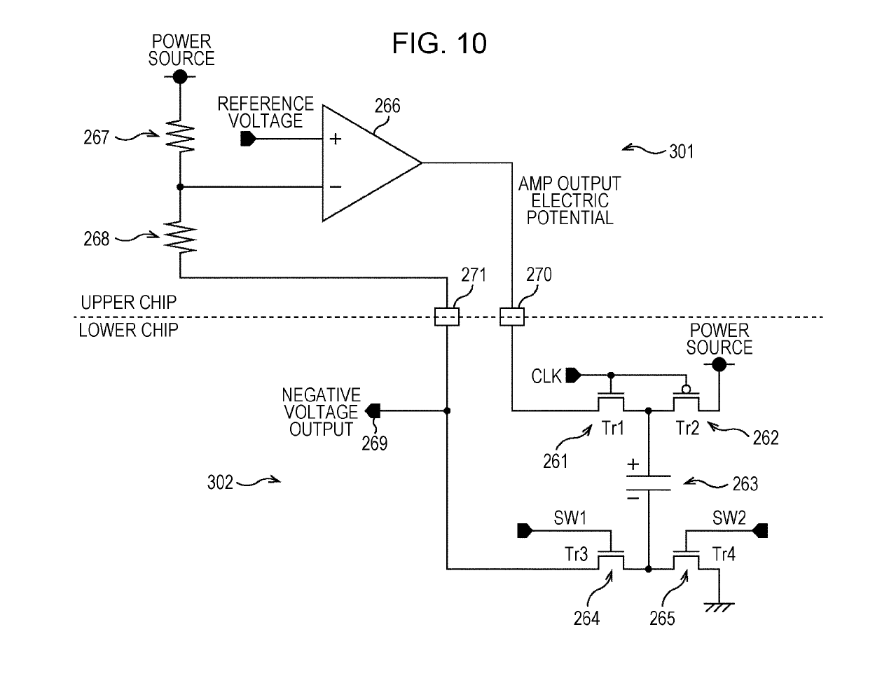

Moreover, the negative electric potential generation circuit 71 in the solid-state imaging device 11 illustrated in FIG. 9, is described as being divided into the negative electric potential generation sub-circuit 301 and the negative electric potential generation sub-circuit 302, but for example, in this case, the negative electric potential generation circuit 71 is configured as illustrated in more detail in FIG. 10. Moreover, in FIG. 10, like reference numerals are given to like parts that correspond to those in FIG. 9 or those in FIG. 7, and descriptions of the like parts are appropriately omitted.

In FIG. 10, above a dotted line is a region of the upper chip 21 and below the dotted line is a region of the lower chip 22.

In this example, the negative electric potential generation sub-circuit 301 is configured from the amplifier 266, the resistance element 267, and the resistance element 268. Furthermore, the negative electric potential generation sub-circuit 302 is configured from the transistor 261, the transistor 262, the pumping capacitor 263, the transistor 264, the transistor 265, and the negative voltage output node 269.

Moreover, in FIG. 10, the resistance element 268 is electrically connected to the negative voltage output node 269 and the transistor 264 via the contact 271, and the output terminal of the amplifier 266 is electrically connected to the transistor 261 via the contact 270.

In this manner, the negative electric potential generation sub-circuit 301 is configured from elements that are different from the low-breakdown-voltage transistor or the capacitance element, and the negative electric potential generation sub-circuit 302 is configured from several elements that include the capacitance element.

Moreover, even though the negative electric potential generation circuit 71 is configured from the negative electric potential generation sub-circuit 301 and the negative electric potential generation sub-circuit 302, relationships in connection among the parts from the transistors 261 to the negative voltage output node 269 constituting the negative electric potential generation circuit 71 are the same as in FIG. 7. That is, a difference between the negative electric potential generation circuit 71 illustrated in FIG. 7 and the negative electric potential generation circuit 71 illustrated in FIG. 10 is in whether each element is arranged in the upper chip 21 or in the lower chip 22. Therefore, the negative electric potential generation circuit 71 illustrated in FIG. 10 performs the same operation as the operation described referring to FIG. 8 and applies the negative voltage to the vertical drive circuit 63.

### Sixth Embodiment

### Configuration Example of Solid-State Imaging Device

Furthermore, according to the third embodiment described above, the example in which the circuit that does not include the resistance element and the capacitance element is set to be the peripheral circuit 32-1 is described, but one part of one circuit as the peripheral circuit 32 may be integrated into the upper chip 21 and the remaining part including the resistance element or the capacitance element may be integrated into the lower chip 22.

For example, the circuits each of which does not include the low-breakdown-voltage transistor and the resistance element and resistance element are integrated as the peripheral circuit 32-1 into the upper chip 21, and each of the bias generation circuit 70 and the negative electric potential generation circuit 71 is divided into two circuits and the two circuits of each are integrated into the upper chip 21 and the lower chip 22, respectively.

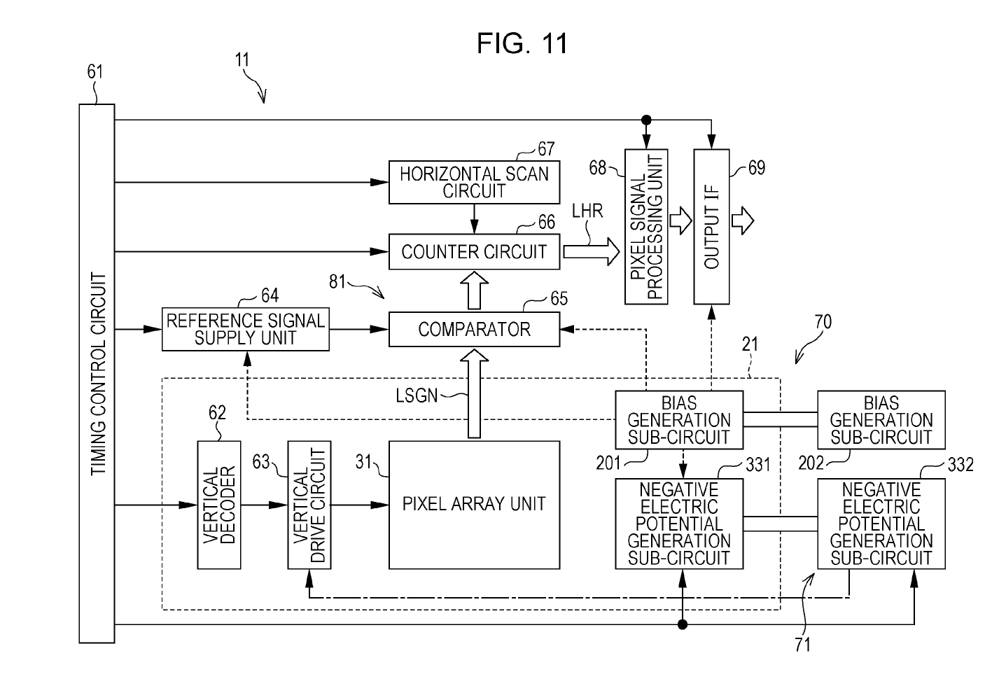

If each circuit is arranged according to this floor plan, for example, the solid-state imaging device 11 is configured as illustrated in FIG. 11. Moreover, in FIG. 11, like reference numerals are given to like parts that correspond to those in FIG. 5, and descriptions of the like parts are appropriately omitted.

According to the floor plan of the solid-state imaging device 11 described in FIG. 11, one bias generation circuit 70 that realizes the function of outputting the reference current to a predetermined circuit is divided into two circuits, the bias generation sub-circuit 201 and the bias generation sub-circuit 202, and the two circuits are integrated into the upper chip 21 and the lower chip 22, respectively. Moreover, as illustrated in FIG. 6, the bias generation sub-circuit 201 has a circuit configuration that includes neither the resistance element nor the capacitance element, and the bias generation sub-circuit 202 has a circuit configuration that includes the resistance element.

Furthermore, one negative electric potential generation circuit 71 that functions as the charge pump is divided into two circuits, a negative electric potential generation sub-circuit 331 and a negative electric potential generation sub-circuit 332, and the two circuits are integrated into the upper chip 21 and the lower chip 22, respectively.

At this point, the negative electric potential generation sub-circuit 331 is a circuit that is made from elements that are different from the low-breakdown-voltage transistor, the resistance element, and the capacitance element, among the elements making up the negative electric potential generation circuit 71, and is arranged in the upper chip 21. Furthermore, the negative electric potential generation sub-circuit 332 is a circuit that is made from several elements that include at least the resistance element or the capacitance element, among the elements making up the negative electric potential generation circuit 71, and is arranged in the lower chip 22.

Then, the negative electric potential generation sub-circuit 331 and the negative electric potential generation sub-circuit 332 are electrically connected to each other via the contact provided between the upper chip 21 and the lower chip 22, and the analog signal is transmitted and received between the negative electric potential generation sub-circuit 331 and the negative electric potential generation sub-circuit 332.

Furthermore, in this example, the pixel array unit 31, and the vertical decoder 62, the vertical drive circuit 63, the bias generation sub-circuit 201, and the negative electric potential generation sub-circuit 331 as the peripheral circuits 32-1 are integrated into the upper chip 21.

Furthermore, the timing control circuit 61, the reference signal supply unit 64, the comparator 65, the counter circuit 66, the horizontal scan circuit 67, the pixel signal processing unit 68, the output IF 69, the bias generation sub-circuit 202, and the negative electric potential generation sub-circuit 332 are integrated as the peripheral circuits 32-2 into the lower chip 22.

Because also in the solid-state imaging device 11 illustrated in FIG. 11, the peripheral circuit 32 is provided in each of the lower chip 22 and the upper chip 21 that is laminated on the lower chip 22, making the solid-state imaging device 11 smaller can be accomplished by the circuit arrangement that has the high degree of freedom. Particularly, each of the bias generation circuit 70 and the negative electric potential generation circuit 71 that realize one function is divided into two sub-circuits, and the two sub-circuits of each are arranged in the upper chip 21 and the lower chip 22, respectively. Thus, the floor plan for the high degree of freedom can be further accomplished. Accordingly, the optimization of the chip size of the solid-state imaging device 11 can be more simply performed, and further making the solid-state imaging device 11 smaller can be accomplished.

Furthermore, in the solid-state imaging device 11, all the peripheral circuits 32 each of which includes the resistance element or the capacitance element, which are a cause for increasing the mask cost, are arranged in the lower chip 22, and thus the manufacturing cost of the solid-state imaging device 11 can be further suppressed.

Configuration Example of Negative Electric Potential Generation Circuit

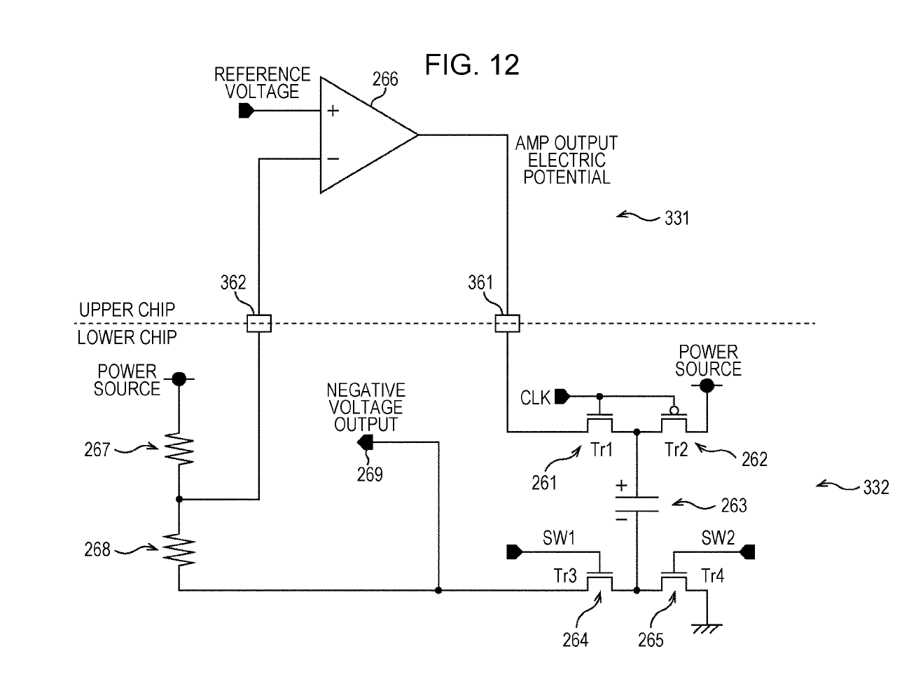

Moreover, the negative electric potential generation circuit 71 in the solid-state imaging device 11 illustrated in FIG. 11, is described as being divided into the negative electric potential generation sub-circuit 331 and the negative electric potential generation sub-circuit 332, but for example, in this case, the negative electric potential generation circuit 71 is configured as illustrated in more detail in FIG. 12. Moreover, in FIG. 12, like reference numerals are given to like parts that correspond to those in FIG. 7, and descriptions of the like parts are appropriately omitted.

In FIG. 12, above a dotted line is a region of the upper chip 21 and below the dotted line is a region of the lower chip 22.

In this example, the negative electric potential generation sub-circuit 331 is configured from the amplifier 266. Furthermore, the negative electric potential generation sub-circuit 332 is configured from the transistor 261, the transistor 262, the pumping capacitor 263, the transistor 264, the transistor 265, the resistance element 267, the resistance element 268, and the negative voltage output node 269.

Moreover, in FIG. 12, the output terminal of the amplifier 266 is electrically connected to the transistor 261 via the contact 361, and the negative-side input terminal of the amplifier 266 is electrically connected to the resistance element 267 and the resistance element 268 via the contact 362.

In this manner, the negative electric potential generation sub-circuit 331 is configured from elements that are different from the low-breakdown-voltage transistor, the resistance element and the capacitance element, and the negative electric potential generation sub-circuit 332 is configured from several elements that include the resistance element and the capacitance element.

Moreover, even though the negative electric potential generation circuit 71 is configured from the negative electric potential generation sub-circuit 331 and the negative electric potential generation sub-circuit 332, relationships in connection among the parts from the transistors 261 to the negative voltage output node 269 are the same as in FIG. 7. That is, a difference between the negative electric potential generation circuit 71 illustrated in FIG. 7 and the negative electric potential generation circuit 71 illustrated in FIG. 12 is in whether each element is arranged in the upper chip 21 or in the lower chip 22. Therefore, the negative electric potential generation circuit 71 illustrated in FIG. 12 performs the same operation as the operation described referring to FIG. 8 and applies the negative voltage to the vertical drive circuit 63.

Coping with a Noise Problem with an Analog Signal

Incidentally, as is the case with the negative electric potential generation sub-circuit 331 and the negative electric potential generation sub-circuit 332, if the peripheral circuit 32 is divided into two sub-circuits and the two sub-circuits are arranged in the upper chip 21 and lower chip 22, it necessary to cope with a noise problem with a signal line for the analog signal, which electrically connects the upper chip 21 and lower chip 22.

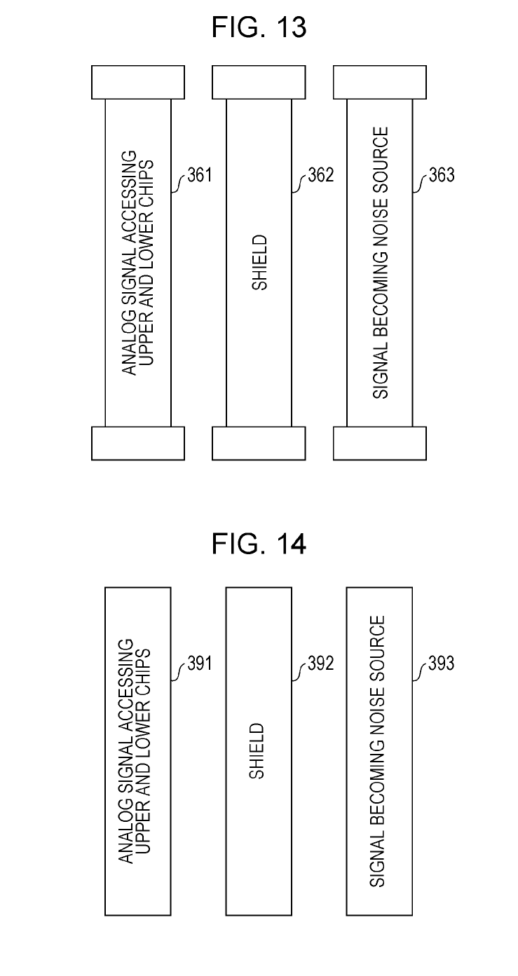

For example, as illustrated in FIG. 13, if the contact 361 for the analog signal is provided between the upper chip 21 and the lower chip 22, the contact 362 that functions as a shield may be arranged between the contact 361 and the contact 363 for the signal that becomes a noise source.

In FIG. 13, for example, each contract is illustrated when FIG. 1 is viewed from a depth direction. That is, upper ends of the contact 361 to the contact 363 in FIG. 13 indicate end portions of the contacts provided in the upper chip 21, and lower ends of the contact 361 to the contact 363 in FIG. 13 indicate end portions of the contacts provided in the lower chip 22.

For example, the contacts 361 that connect signal lines for the analog signal, which are provided in the upper chip 21 and the lower chip 22 are defined as the contact 362 and the contact 361 in FIG. 12, defined as the contact 236 and the contact 237 in FIG. 6, and so on.

Furthermore, representative examples of the noise source are the clock and the control signal that are output from the timing control circuit 61, the low-breakdown-voltage power source, the low-breakdown-voltage ground and so forth. Therefore, for example, if the negative electric potential generation circuit 71 is configured as illustrated in FIG. 7, the contact for electrically connecting the signal line, connecting the timing control circuit 61 and the gate of the transistor 261, between the upper chip 21 and the lower chip 22 and the like is defined as the contact 363.

Moreover, the contact for electrically connecting the signal lines for the high-breakdown-voltage power source and the high-breakdown-voltage ground between the upper chip 21 and the lower chip 22 may be used as the contact 362 that functions as the shield.

For example, the high-breakdown-voltage power source is the power source connected to the resistance element 267 or the power source connected to the transistor 262 in FIG. 12, or the power source connected to the transistor 233 and the transistor 234 in FIG. 6, and the like. Furthermore, for example, the high-breakdown-voltage ground is the ground connected to the transistor 265 in FIG. 12, or the ground connected to the resistance element 235 in FIG. 6.

In this manner, the contact 362 that functions as the shield is arranged between the contact 361 that connects the signal line for the analog signal between the upper and lower chips and the contact 363 that connects the signal line that becomes the noise source, and thus the noise that occurs in the contact 361 due to an influence of the contact 363 can be suppressed. That is, the noise that the analog signal receives from the noise source can be suppressed by the shield.

The measure to cope with the noise problem in this manner is possible not only in the contact, the connection part between the chips, but also in wiring in the chip.

For example, in a case of electrically connecting the signal line for the analog signal between the upper chip 21 and the lower chip 22, the long-distance wiring via the contact is necessary. At this time, if the signal line that becomes the noise source is present in the vicinity of the signal line for the analog signal, the analog signal is influenced by a signal that becomes the noise source and thus the noise occurs in the analog signal.

Accordingly, for example, as illustrated in FIG. 14, if a signal line 392 that functions as the shield is provided between a signal line 391 for the analog signal and a signal line 393 for the signal that becomes the noise source, an occurrence of the noise that results from the analog signal can be effectively suppressed.

Moreover, in FIG. 14, for example, the upper chip 21 or lower chip 22 in FIG. 1 is indicated with the signal lines such as the peripheral circuit 32, when viewed from above in FIG. 1.

For example, the signal line 391 is defined as the signal line and the like provided in the upper chip 21, among the signal lines that link the amplifier 266 in the upper chip 21 and the resistance element 267 in the lower chip 22 in FIG. 12. In such a case, the signal line 391 to the signal line 393 are wired in such a manner as to be in the direction parallel to a surface of the upper chip 21.

Representative examples of the noise source are the clock and the control signal that are output from the timing control circuit 61, the low-breakdown-voltage power source, the low-breakdown-voltage voltage ground and so forth. Therefore, for example, the signal line 393 for the signal that becomes the noise source is a signal line that is provided between the timing control circuit 61 and the negative electric potential generation sub-circuit 331.

Furthermore, the signal line 392 that functions as the shield is set as to be a signal line for the high-breakdown-voltage power source or the high-breakdown-voltage ground.

In this manner, the signal line 392 that functions as the shield is arranged between the signal line 391 for the analog signal and the signal line 393 that becomes the noise source, and thus the occurrence of the noise in the signal line 391 that results from the signal line 393 can be suppressed.

Moreover, the measure to cope with the noise problem, described referring to FIG. 13 and FIG. 14, is not limited to the solid-state imaging device 11 according to the sixth embodiment, and of course, can be applied to the solid-state imaging devices 11 according to the first to fifth embodiments.

Configuration Example of an Electronic Apparatus

Incidentally, the case where the present technology is applied to the solid-state imaging device is described above, but the present technology is limited to the solid-state imaging device and can be applied to an electronic apparatus such as a digital camera or a video camcorder as well.

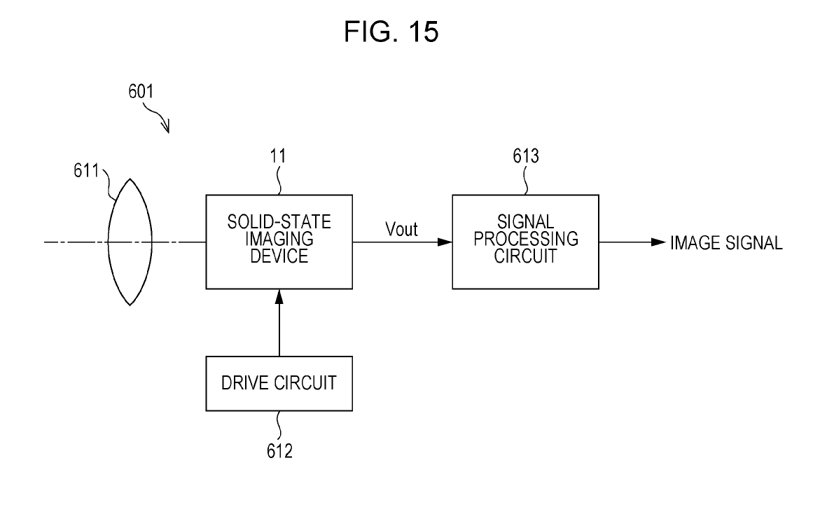

For example, if the present technology is applied to the electronic apparatus that has the solid-state imaging device 11 described above, such an electronic apparatus is configured as illustrated in FIG. 15. Moreover, in FIG. 15, like reference numerals are given to like parts that correspond to those in FIG. 1, and descriptions of the like parts are appropriately omitted.

An electronic apparatus 601 illustrated in FIG. 15 has the solid-state imaging device 11 described above. Furthermore, the electronic apparatus 601 has a lens 611, as an optical system that guides incident light into the pixel array unit 31 of the solid-state imaging device 11 and images a photography object, which images the incident light on an imaging surface.

Furthermore, the electronic apparatus 601 has a drive circuit 612 that drives the solid-state imaging device 11 and a signal processing circuit 613 that processes an output signal from the solid-state imaging device 11.

The drive circuit 612 has a timing generator that generates various timing signals that include a start pulse or a clock pulse that drives the circuits within the solid-state imaging device 11, and drives the solid-state imaging device 11 with a predetermined timing signal.

Furthermore, the signal processing circuit 613 performs predetermined signal processing on the output signal from the solid-state imaging device 11. The image signal that is processed in the signal processing circuit 613 is recorded, for example, in a recording medium, such as a memory. Image information recorded in the recording medium is printed out for hard copy by a printer and the like. Furthermore, the image signal that is processed in the signal processing circuit 613 is projected, as a moving image, on a monitor made from a liquid crystal display and others.

As described above, in the electronic apparatus such as the digital camera, a high-precision camera, when equipped with the solid-state imaging device 11, can be realized.

Furthermore, the example in which the solid-state imaging device 11 is made from the CMOS image sensor is described above, but the solid-state imaging device 11 may be configured from a backside irradiation type CMOS image sensor, a charge coupled device (CCD) or the like.

Note that the presently disclosed technology can also adopt the following configurations:

A. A solid-state imaging device, comprising:

a first substrate, the first substrate including:
a pixel array unit;
a peripheral circuit;

a second substrate, wherein the second substrate is stacked on the first substrate, the second substrate including:
a peripheral circuit, wherein the peripheral circuit of the second substrate includes at least one of a resistance element or a capacitance element,
   wherein one of:
      the peripheral circuit of the second substrate includes a resistance element and the peripheral circuit of the first substrate does not include a resistance element, and
      the peripheral circuit of the second substrate includes a capacitance element and the peripheral circuit of the first substrate does not include a capacitance element, and
      the peripheral circuit of the second substrate includes both a resistance element and a capacitance element, and wherein the peripheral circuit of the first substrate includes neither a resistance element nor a capacitance element.

B. The solid-state imaging device of claim A, wherein the peripheral circuit of the second substrate includes a resistance element, and wherein the peripheral circuit of the first substrate does not include a resistance element.

C. The solid-state imaging device of claims A or B, wherein the peripheral circuit of the first substrate further includes a comparator.

D. The solid-state imaging device of any of claims A to C, wherein the peripheral circuit of the first substrate further includes a vertical decoder and a vertical drive circuit.

E. The solid-state imaging device of any of claims A-D, wherein the first substrate does not include a capacitance element.

F. The solid-state imaging device of any of claims A-D, wherein the peripheral circuit of the second substrate includes a capacitance element, and wherein the peripheral circuit of the first substrate does not include a capacitance element.

G. The solid-state imaging device of any of claims A-F, wherein the peripheral circuit of the first substrate further includes a reference signal supply unit and a bias generation circuit.

H. The solid-state imaging device of any of claims A-C or E-G, wherein the peripheral circuit of the first substrate further includes a vertical decoder and a vertical drive circuit.

I. The solid-state imaging device of any of claims A-G, wherein the peripheral circuit of the second substrate further includes a timing control circuit, a comparator, a counter circuit, a horizontal scan circuit, and pixel signal processing unit, an output IF, and a negative electric potential generation circuit.

J. The solid-state imaging device of any of claims A-I, wherein the first substrate does not include a resistance element.

K. The solid-state imaging device of claim A, wherein the peripheral circuit of the second substrate includes both a resistance element and a capacitance element, and wherein the peripheral circuit of the first substrate includes neither a resistance element nor a capacitance element.

L. An electronic apparatus, comprising:

an optical system;

a solid-state imaging device, wherein the solid-state imaging device receives light from the optical system, the solid-state imaging device including:
a first substrate, the first substrate including:
   a pixel array unit;
   a peripheral circuit;
a second substrate, wherein the second substrate is stacked on the first substrate, the second substrate including:
   a peripheral circuit, wherein the peripheral circuit of the second substrate includes at least one of a resistance element or a capacitance element,
   wherein one of:
      the peripheral circuit of the second substrate includes a resistance element and the peripheral circuit of the first substrate does not include a resistance element, and
      the peripheral circuit of the second substrate includes a capacitance element and the peripheral circuit of the first substrate does not include a capacitance element, and
      the peripheral circuit of the second substrate includes both a resistance element and a capacitance element, and wherein the peripheral circuit of the first substrate includes neither a resistance element nor a capacitance element;

a drive circuit, wherein the drive circuit generates timing signals provided to the solid-state imaging device;

a signal processing circuit, wherein the signal processing circuit performs signal processing on an output signal from the solid-state imaging device.

M. The electronic apparatus of claim L, wherein the peripheral circuit of the second substrate includes a resistance element, and wherein the peripheral circuit of the first substrate does not include a resistance element.

N. The electronic apparatus of claims L or M, wherein the first substrate does not include a capacitance element.

O. The electronic apparatus of any of claims L-N, wherein the peripheral circuit of the second substrate includes a capacitance element, and wherein the peripheral circuit of the first substrate does not include a capacitance element.

P. The electronic apparatus of claim L, wherein the peripheral circuit of the second substrate includes both a resistance element and a capacitance element, and wherein the peripheral circuit of the first substrate includes neither a resistance element nor a capacitance element.

Q. An imaging device, comprising:

a first substrate;

a second substrate, wherein the first substrate is stacked on the second substrate;

a pixel array unit, wherein the pixel array unit is included in the first substrate;

a comparator, wherein the comparator is included in a first one of the first substrate and the second substrate;

a reference signal supply unit, wherein the reference signal supply unit is included in a second one of the first substrate and the second substrate;

a bias generation circuit, wherein the bias generation unit is included in the second one of the first substrate and the second substrate.

R. The imaging device of claim Q, wherein the comparator is included in the first substrate, wherein the reference signal supply unit and the bias generation circuit are included in the second substrate, wherein the first substrate includes capacitance elements, and wherein the second substrate includes resistance elements.

S. The imaging device of claims Q or R, wherein the second substrate does not include any capacitance elements.

T. The imaging device of claim Q, wherein the comparator is included in the second substrate, wherein the reference signal supply unit and the bias generation circuit are included in the first substrate, wherein the first substrate includes resistance elements, wherein the second substrate includes capacitance elements, and wherein the second substrate does not include any resistance elements.

Moreover, embodiments of the present technology are not limited to the embodiments described above and various modifications can be made within a scope not deviating from the gist of the present technology.

What is claimed is:

1. A solid-state imaging device, comprising:
a first substrate, the first substrate including:
a pixel array unit;
a peripheral circuit;
a second substrate, wherein the second substrate is stacked on the first substrate, the second substrate including:
a peripheral circuit, wherein the peripheral circuit of the second substrate includes at least one of a resistance element or a capacitance element,
wherein one of:
the peripheral circuit of the second substrate includes a resistance element and the peripheral circuit of the first substrate does not include a resistance element, and
the peripheral circuit of the second substrate includes a capacitance element and the peripheral circuit of the first substrate does not include a capacitance element, and
the peripheral circuit of the second substrate includes both a resistance element and a capacitance element, and wherein the peripheral circuit of the first substrate includes neither a resistance element nor a capacitance element.

2. The solid-state imaging device of claim 1, wherein the peripheral circuit of the second substrate includes a resistance element, and wherein the peripheral circuit of the first substrate does not include a resistance element.

3. The solid-state imaging device of claim 2, wherein the peripheral circuit of the first substrate further includes a comparator.

4. The solid-state imaging device of claim 3, wherein the peripheral circuit of the first substrate further includes a vertical decoder and a vertical drive circuit.

5. The solid-state imaging device of claim 2, wherein the first substrate does not include a capacitance element.

6. The solid-state imaging device of claim 1, wherein the peripheral circuit of the second substrate includes a capacitance element, and wherein the peripheral circuit of the first substrate does not include a capacitance element.

7. The solid-state imaging device of claim 6, wherein the peripheral circuit of the first substrate further includes a reference signal supply unit and a bias generation circuit.

8. The solid-state imaging device of claim 7, wherein the peripheral circuit of the first substrate further includes a vertical decoder and a vertical drive circuit.

9. The solid-state imaging device of claim 8, wherein the peripheral circuit of the second substrate further includes a timing control circuit, a comparator, a counter circuit, a horizontal scan circuit, and pixel signal processing unit, an output IF, and a negative electric potential generation circuit.

10. The solid-state imaging device of claim 6, wherein the first substrate does not include a resistance element.

11. The solid-state imaging device of claim 1, wherein the peripheral circuit of the second substrate includes both a resistance element and a capacitance element, and wherein the peripheral circuit of the first substrate includes neither a resistance element nor a capacitance element.

12. An electronic apparatus, comprising:
an optical system;
a solid-state imaging device, wherein the solid-state imaging device receives light from the optical system, the solid-state imaging device including:
a first substrate, the first substrate including:
a pixel array unit;
a peripheral circuit;
a second substrate, wherein the second substrate is stacked on the first substrate, the second substrate including:
a peripheral circuit, wherein the peripheral circuit of the second substrate includes at least one of a resistance element or a capacitance element,
wherein one of:
the peripheral circuit of the second substrate includes a resistance element and the peripheral circuit of the first substrate does not include a resistance element, and
the peripheral circuit of the second substrate includes a capacitance element and the peripheral circuit of the first substrate does not include a capacitance element, and
the peripheral circuit of the second substrate includes both a resistance element and a capacitance element, and wherein the peripheral circuit of the first substrate includes neither a resistance element nor a capacitance element;
a drive circuit, wherein the drive circuit generates timing signals provided to the solid-state imaging device;
a signal processing circuit, wherein the signal processing circuit performs signal processing on an output signal from the solid-state imaging device.

13. The electronic apparatus of claim 12, wherein the peripheral circuit of the second substrate includes a resistance element, and wherein the peripheral circuit of the first substrate does not include a resistance element.

14. The electronic apparatus of claim 13, wherein the first substrate does not include a capacitance element.

15. The electronic apparatus of claim 12, wherein the peripheral circuit of the second substrate includes a capacitance element, and wherein the peripheral circuit of the first substrate does not include a capacitance element.

16. The electronic apparatus of claim 12, wherein the peripheral circuit of the second substrate includes both a resistance element and a capacitance element, and wherein the peripheral circuit of the first substrate includes neither a resistance element nor a capacitance element.

17. An imaging device, comprising:
a first substrate;
a second substrate, wherein the first substrate is stacked on the second substrate;
a pixel array unit, wherein the pixel array unit is included in the first substrate;
a comparator, wherein the comparator is included in a first one of the first substrate and the second substrate;
a reference signal supply unit, wherein the reference signal supply unit is included in a second one of the first substrate and the second substrate;
a bias generation circuit, wherein the bias generation unit is included in the second one of the first substrate and the second substrate.

18. The imaging device of claim 17, wherein the comparator is included in the first substrate, wherein the reference signal supply unit and the bias generation circuit are included in the second substrate, wherein the first substrate includes capacitance elements, and wherein the second substrate includes resistance elements.

19. The imaging device of claim 18, wherein the second substrate does not include any capacitance elements.

20. The imaging device of claim 17, wherein the comparator is included in the second substrate, wherein the reference signal supply unit and the bias generation circuit are included in the first substrate, wherein the first substrate includes resistance elements, wherein the second substrate includes capacitance elements, and wherein the second substrate does not include any resistance elements.
